(19) United States
(12) Patent Application Publication
(10) Pub. No.: US 2024/0347446 A1
(43) Pub. Date: Oct. 17, 2024

(54) LATERAL COILS USED FOR ENERGY TRANSFER OVER ISOLATION REGION IN MULTI-VOLTAGE DEVICES

(71) Applicant: Infineon Technologies AG, Neubiberg (DE)

(72) Inventor: Hermann GRUBER, Wörth a. D. (DE)

(21) Appl. No.: 18/300,638

(22) Filed: Apr. 14, 2023

(51) Int. Cl. H01L 23/522; H01L 27/13

(52) U.S. Cl. CPC H01L 23/5227; H01L 27/13; H01L 28/10

(57) ABSTRACT

A multi-voltage domain device includes a circuit substrate comprising a first region comprising first circuitry, a second region comprising second circuitry, and an isolation region that electrically isolates the first region and the second region in a lateral direction; an insulator layer arranged on the circuit substrate; a first coil arranged in the insulator layer and electrically coupled to the first circuitry; a second coil arranged in the insulator layer, electrically coupled to the first circuitry, and laterally separated from the first coil in the lateral direction by an insulator material of the insulator layer. The first coil and the second coil have respective center axes around which respective windings are wound, that extend parallel to the lateral direction, and are aligned with each other. The first coil and the second coil are magnetically coupled to each other in the lateral direction.

### BACKGROUND

A high voltage (HV) gate driver circuit may include a low voltage (LV) gate driver used to drive a low-side transistor switch and an HV gate driver used to drive a high-side transistor switch. The LV gate driver is arranged in a low voltage domain, whereas the HV gate driver is arranged in a high voltage domain. In practice, the gate driver also includes a termination region that isolates the high voltage domain from the low voltage domain, and may be referred to as an isolation termination region. Thus, the isolation termination region provides a high voltage isolation barrier between the two voltage domains such that the two voltage domains remain electrically isolated from each other.

### SUMMARY

In some implementations, a multi-voltage domain device includes a circuit substrate comprising a first main surface and a second main surface arranged opposite to the first main surface, wherein the circuit substrate comprises: a first region comprising first circuitry that operates in a first voltage domain, a second region comprising second circuitry that operates in a second voltage domain, and an isolation region that electrically isolates the first region and the second region in a lateral direction that extends parallel to the first main surface and the second main surface; an insulator layer arranged on the first main surface of the circuit substrate; a first coil arranged in the insulator layer, wherein the first coil is electrically coupled to the first circuitry and is isolated from the second region, wherein the first coil has a first center axis around which first windings of the first coil are wound, and wherein the first center axis extends parallel to the lateral direction; and a second coil arranged in the insulator layer and laterally separated from the first coil in the lateral direction by an insulator material of the insulator layer, wherein the second coil is electrically coupled to the second circuitry and is isolated from the first region, wherein the second coil has a second center axis around which second windings of the second coil are wound, and wherein the second center axis extends parallel to the lateral direction and is aligned with the first center axis, wherein the first coil and the second coil are magnetically coupled to each other in the lateral direction based on an alignment of the first center axis with the second center axis.

In some implementations, a multi-voltage domain device includes a semiconductor layer comprising a first main surface and a second main surface arranged opposite to the first main surface, wherein the semiconductor layer comprises: a first region comprising first circuitry, a second region comprising second circuitry, and an isolation region that electrically isolates the first region and the second region in a lateral direction in order to electrically isolate the first circuitry and the second circuitry, wherein the lateral direction extends parallel to the first main surface and the second main surface; an insulator layer arranged on the first main surface of the semiconductor layer; a first coil arranged in the insulator layer, wherein the first coil is electrically coupled to the first circuitry and is isolated from the second region, wherein the first coil has a first center axis around which first windings of the first coil are wound, wherein the first windings define a first core area of the first coil that extends along the first center axis, and wherein the first center axis extends parallel to the lateral direction; and a second coil arranged in the insulator layer and laterally separated from the first coil in the lateral direction by an insulator material of the insulator layer, wherein the second coil is electrically coupled to the second circuitry and is isolated from the first region, wherein the second coil has a second center axis around which second windings of the second coil are wound, wherein the second windings define a second core area of the second coil that extends along the second center axis, and wherein the second center axis extends parallel to the lateral direction, wherein the first core area is at least partially aligned with the second core area in the lateral direction, wherein the first coil and the second coil are magnetically coupled to each other in the lateral direction based on an alignment of the first core area with the second core area.

In some implementations, a multi-voltage domain device includes a circuit substrate comprising a first main surface and a second main surface arranged opposite to the first main surface, wherein the circuit substrate comprises: a first region comprising first circuitry, a second region comprising second circuitry, a third region comprising third circuitry, and at least one isolation region that electrically isolates the first region and the second region in a first lateral direction in order to electrically isolate the first circuitry and the second circuitry, electrically isolates the first region and the third region in the first lateral direction in order to electrically isolate the first circuitry and the third circuitry, and electrically isolates the second region and the third region in a second lateral direction in order to electrically isolate the second circuitry and the third circuitry; an insulator layer arranged on the first main surface of the circuit substrate; a first coil arranged in the insulator layer, wherein the first coil is electrically coupled to the first circuitry and is isolated from the second region and the third region, wherein the first coil has a first center axis around which first windings of the first coil are wound, wherein the first windings define a first core area of the first coil that extends along the first center axis, and wherein the first center axis extends parallel to the first lateral direction; a second coil arranged in the insulator layer and laterally separated from the first coil in the first lateral direction by an insulator material of the insulator layer, wherein the second coil is electrically coupled to the second circuitry and is isolated from the first region and the third region, wherein the second coil has a second center axis around which second windings of the second coil are wound, wherein the second windings define a second core area of the second coil that extends along the second center axis, and wherein the second center axis extends parallel to the first lateral direction; and a third coil arranged in the insulator layer, laterally separated from the first coil in the first lateral direction by the insulator material of the insulator layer and laterally separated from the second coil in the second lateral direction by the insulator material of the insulator layer, wherein the third coil is electrically coupled to the third circuitry and is isolated from the first region and the second region, wherein the third coil has a third center axis around which third windings of the third coil are wound, wherein the third windings define a third core area of the third coil that extends along the third center axis, and wherein the third center axis extends parallel to the first lateral direction, wherein the second core area is at least partially aligned with the first core area in the first lateral direction, wherein the third core area is at least partially aligned with the first core area in the first lateral direction, wherein the first coil and the second coil are magnetically coupled to each other in the first lateral direction based on an alignment of the first core area with the second core area, and wherein the first coil and the third coil are magnetically coupled to each other in the first lateral direction based on an alignment of the first core area with the third core area.

In some implementations, a multi-voltage domain device includes a circuit substrate comprising a first main surface and a second main surface arranged opposite to the first main surface, wherein the circuit substrate comprises: a first region comprising first circuitry, a second region comprising second circuitry and third circuitry, and an isolation region that electrically isolates the first region and the second region in a lateral direction in order to electrically isolate the first circuitry from the second circuitry and the first circuitry from the third circuitry, wherein the lateral direction extends parallel to the first main surface and the second main surface; an insulator layer arranged on the first main surface of the circuit substrate; a first coil arranged in the insulator layer, wherein the first coil is electrically coupled to the first circuitry and is isolated from the second region, wherein the first coil has a first center axis around which first windings of the first coil are wound, wherein the first windings define a first core area of the first coil that extends along the first center axis, and wherein the first center axis extends parallel to the lateral direction; a second coil arranged in the insulator layer and laterally separated from the first coil in the lateral direction by an insulator material of the insulator layer, wherein the second coil is electrically coupled to the second circuitry and is isolated from the first region, wherein the second coil has a second center axis around which second windings of the second coil are wound, wherein the second windings define a second core area of the second coil that extends along the second center axis, and wherein the second center axis extends parallel to the lateral direction; and a third coil arranged in the insulator layer and laterally separated from the first coil in the lateral direction by the insulator material of the insulator layer, wherein the third coil is electrically coupled to the third circuitry and is isolated from the first region, wherein the third coil has a third center axis around which third windings of the third coil are wound, wherein the third windings define a third core area of the third coil that extends along the third center axis, and wherein the third center axis extends parallel to the lateral direction, wherein the second core area is at least partially aligned with the first core area in the lateral direction, wherein the third core area is at least partially aligned with the first core area in the lateral direction, wherein the first coil and the second coil are magnetically coupled to each other in the lateral direction based on an alignment of the first core area with the second core area, and wherein the first coil and the third coil are magnetically coupled to each other in the lateral direction based on an alignment of the first core area with the third core area.

### BRIEF DESCRIPTION OF THE DRAWINGS

Implementations are described herein making reference to the appended drawings.

FIG. 1A illustrates a top view of a multi-voltage domain device according to one or more implementations.

FIG. 1B illustrates a multi-voltage domain device according to one or more implementations.

FIG. 2A illustrates a multi-voltage domain device according to one or more implementations.

FIG. 2B illustrates a side view of the multi-voltage domain device according to one or more implementations.

FIG. 2C illustrates a side view of a multi-voltage domain device according to one or more implementations.

FIG. 2D illustrates a top view of a portion of a multi-voltage domain device according to one or more implementations.

FIG. 3 illustrates a top view of a lateral transformer circuit according to one or more implementations.

FIG. 4 illustrates a top view of a lateral transformer circuit according to one or more implementations.

FIG. 5 illustrates a top view of a lateral transformer circuit according to one or more implementations.

FIG. 6 illustrates a top view of a lateral transformer circuit according to one or more implementations.

FIG. 7 illustrates a top view of a lateral transformer circuit according to one or more implementations.

FIG. 8 illustrates a top view of a lateral transformer circuit according to one or more implementations.

### DETAILED DESCRIPTION

In the following, details are set forth to provide a more thorough explanation of example implementations. However, it will be apparent to those skilled in the art that these implementations may be practiced without these specific details. In other instances, well-known structures and devices are shown in block diagram form or in a schematic view rather than in detail in order to avoid obscuring the implementations. In addition, features of the different implementations described hereinafter may be combined with each other, unless specifically noted otherwise.

Further, equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually exchangeable.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “top,” “bottom,” “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling, e.g., any connection or coupling without additional intervening elements, may also be implemented by an indirect connection or coupling, e.g., a connection or coupling with one or more additional intervening elements, or vice versa, as long as the general purpose of the connection or coupling, for example, to transmit a certain kind of signal or to transmit a certain kind of information, is essentially maintained. Features from different implementations may be combined to form further implementations. For example, variations or modifications described with respect to one of the implementations may also be applicable to other implementations unless noted to the contrary.

As used herein, the terms “substantially” and “approximately” mean “within reasonable tolerances of manufacturing and measurement.” For example, the terms “substantially” and “approximately” may be used herein to account for small manufacturing tolerances or other factors (e.g., within 5%) that are deemed acceptable in the industry without departing from the aspects of the implementations described herein. For example, a resistor with an approximate resistance value may practically have a resistance within 5% of the approximate resistance value. As another example, an approximate signal value may practically have a signal value within 5% of the approximate signal value.

In the present disclosure, expressions including ordinal numbers, such as “first”, “second”, and/or the like, may modify various elements. However, such elements are not limited by the above expressions. For example, the above expressions do not limit the sequence and/or importance of the elements. The above expressions are used merely for the purpose of distinguishing an element from the other elements. For example, a first box and a second box indicate different boxes, although both are boxes. For further example, a first element could be termed a second clement, and similarly, a second element could also be termed a first element without departing from the scope of the present disclosure.

Multi-voltage domain devices, such as HV gate driver circuits, typically need a way to transmit signals between two electrically-isolated voltage domains. For example, in an HV gate driver circuit that includes an LV domain and an HV domain, an HV gate driver used to drive a high-side transistor switch may receive control signals and possibly other communication signals from circuitry located in the LV domain. In addition, faults that may occur in the HV domain may be communicated from circuitry located in the HV domain to the circuitry located in the LV domain. Accordingly, signals may be transmitted from the LV domain through a termination region to the HV domain, or vice versa.

The signals may be transferred over a vertical transformer. However, vertical transformers require an insulating material, such as an InterLayerDielectric (ILD), to isolate two vertically facing windings (e.g., coils) of the vertical transformer. The insulating material may be, for example, silicon oxide or imide, both of which have poor magnetic permeability μᵣ (i.e., close to 1). Thus, a good coupling between the windings is not achieved. Moreover, it can be difficult, for such a vertical geometry on an integrated circuit (IC) level, to insert material with a high magnetic permeability between the windings in an attempt to provide better coupling of the windings. This is because an area between the windings is typically required for wire-bonding and does not allow the insertion of additional (magnetic) material or for a full encapsulation of the vertical transformer's geometry. As a result, magnetic fields produced by the windings are unguided and go astray (e.g., referred to as stray-fields). Thus, the windings of the vertical transformer are inefficient at energy transfer. In other words, due to the strong magnetic stray-fields of the unguided and unconcentrated magnetic field that couples the windings, the efficiency of energy transfer is poor, and the vertical transformer is often limited by driving losses of a primary winding of the two windings.

Moreover, the ILD thickness dictates an isolation range. Increasing isolation requires changing the ILD and therefore changing the manufacturing process, including requiring a change in a certain minimum number of metal layers to guarantee enough ILD between the primary and the secondary coils and/or a special back-end-of-line (BEOL) process. These vertical arrangements to accommodate different levels of isolation are thus costly and inefficient from a manufacturing point of view and are not practical for HV gate driver processing.

Some implementations disclosed herein are directed to a multi-voltage domain device that uses a lateral transformer that includes two coils that each have a respective center axis that extends in a lateral direction. For example, a first coil of the lateral transformer may have a first center axis that extends parallel to the lateral direction and around which first windings of the first coil are wound. The first windings may define a first core area of the first coil that extends along the first center axis. Additionally, a second coil of the lateral transformer may have a second center axis that extends parallel to the lateral direction and around which second windings of the second coil are wound. The second windings define a second core area of the second coil that extends along the second center axis. The first core area is at least partially aligned with the second core area in the lateral direction. Moreover, the first coil and the second coil are magnetically coupled to each other in the lateral direction based on an alignment of the first core area with the second core area. In some implementations, the first center axis is aligned with (e.g., collinear with) the second center axis and the first coil and the second coil are magnetically coupled to each other in the lateral direction based on an alignment of the first center axis with the second center axis.

The lateral alignment of the first coil and the second coil may provide an improved magnetic coupling (e.g., stronger or increased coupling factor) between the first coil and the second coil, which results in improved energy transfer between the two coils and higher transformer efficiency. The lateral alignment of the first coil and the second coil may also reduce stray fields. With a coupling factor between the two coils increased, a transmission ratio (e.g., also referred to as a transformation ratio or a turns ratio) between the two coils can be used to accurately set an output voltage of the transformer (e.g., an output voltage of the secondary coil) based on a transformer equation Vout=N2/N1×Vin, where Vin is an input voltage supplied across the first coil, N1 is a number of turns of the first coil, N2 is a number of turns of the second coil, and Vout is the output voltage across the second coil. For example, the transmission ratio N2/N1 can be relied upon to set the output voltage Vout at a secondary coil with better precision, which enables the output voltage Vout to be set with improved accuracy and reliability.

In contrast, a transformer with poor magnetic coupling between the coils, and thus poor transformer efficiency, may not accurately follow the transformer equation. As a result, it may be difficult to set the output voltage Vout to a desired value or achieve a desired result with a transformer that has lower magnetic coupling and lower transformer efficiency. For example, with lower transformer efficiency, it may be required to set the input voltage Vin to a higher value to achieve a desired output voltage Vout compared with a transformer with a higher transformer efficiency. Not only may it be difficult to estimate the transformer efficiency to account for losses to achieve the desired output voltage Vout, but the higher input voltage consumes more power, which results in higher overall system cost and inefficiencies.

In addition, due to the improved coupling factor, the transmission ratio can be adjusted over a larger range than would otherwise be possible with a lower coupling factor. Thus, the output voltage Vout can be set over a larger range. In addition, due to the improved coupling factor, multiple secondary coils may be coupled to a single primary coil, which may be used to provide multiple secondary voltages at a same time that would not be possible with a lower coupling factor.

The first coil may be electrically coupled to first circuitry that is electrically isolated from second circuity by an isolation region (e.g., an isolation barrier). For example, a semiconductor layer (e.g., a semiconductor substrate) may be provided as a circuit substrate that includes a first main surface, a second main surface arranged opposite to the first main surface, a first region comprising the first circuitry that operates in a first voltage domain, a second region comprising the second circuitry that operates in a second voltage domain, and the isolation region that electrically isolates the first region and the second region in the lateral direction that extends parallel to the first main surface and the second main surface. For example, the isolation region may include one or more trench isolation barriers (e.g., isolation (DTI) barriers) that extend vertically from the first main surface to the second main surface of the semiconductor layer. The second coil may be electrically coupled to the second circuitry. In addition, the first coil and the second coil may be arranged in or otherwise encased in an insulator layer (e.g., an ILD) such that the first coil is isolated from the second circuitry by the insulator layer and the isolation region, and the second coil is isolated from the first circuitry by the insulator layer and the isolation region. The insulator layer with the first coil and the second coil may be arranged on the first main surface of the semiconductor layer. As a result, galvanic isolation between the first circuitry and the second circuity (e.g., between the first region and the second region) is achieved.

In addition, according to a lateral arrangement or spacing between the windings, a thickness of the insulator layer need not be modified to achieve different levels of isolation, as is required in vertical transformers. Therefore, a manufacturing process does not need to be changed vertically to accommodate different isolation ranges for different multi-voltage domain devices and technologies. Instead, the lateral spacing will only call for a different lateral geometry within an already predefined layer as to where metal structures of the windings are laterally formed to accomplish different isolation ranges within the same manufacturing process.

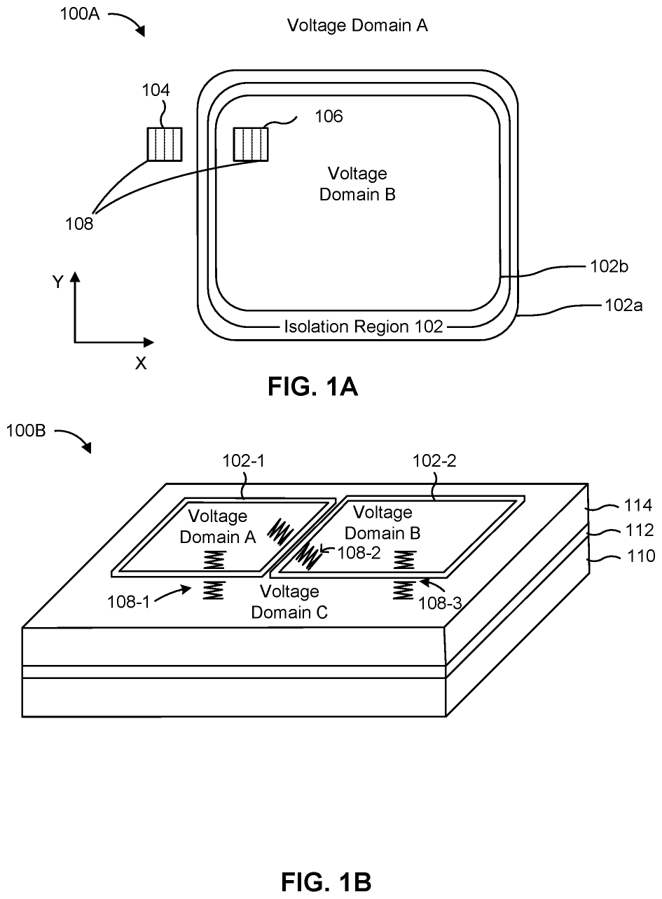

FIG. 1A illustrates a top view of a multi-voltage domain device 100A according to one or more implementations. The multi-voltage domain device 100A may include a first voltage domain (e.g., voltage domain A) that is laterally isolated from a second voltage domain (e.g., voltage domain B) by an isolation region 102. For example, the voltage domain A and the voltage domain B may have different ground potentials. For example, the voltage domain A may be a low-voltage (LV) domain having a first ground potential (e.g., 0V) and the voltage domain B may be a high-voltage (HV) domain having a second ground potential (e.g., a floating ground potential) that is different from the first ground potential. For example, the second ground potential may be greater than the first ground potential and, as a result, the voltage domain B may be referred to as the higher voltage domain. In some implementations, the voltage domain A and the voltage domain B may have a same ground potential, but the voltage domain A and the voltage domain B may include circuitry that require galvanic isolation. In some implementations, the voltage domain A and the voltage domain B may be defined by different voltage ranges (e.g., different supply potentials, such as different HV voltage levels). A larger voltage difference between the first ground potential and the second ground potential may require a greater level of isolation in comparison to a level of isolation required for a smaller voltage difference between the first ground potential and the second ground potential.

In some implementations, the isolation region 102 may be associated with one or more DTI barriers (e.g., vertical trenches at least partially filled with insulator material). For example, the isolation region 102 may include an outermost DTI barrier 102a and an innermost DTI barrier 102b. A quantity of DTI barriers and a lateral dimension of the isolation region 102 can be adjusted based on the desired level of isolation required to isolate the first voltage domain (e.g., voltage domain A) and the second voltage domain (e.g., voltage domain B).

The multi-voltage domain device 100A includes two metal coils, a first coil 104 and a second coil 106, that may be formed on opposite lateral sides of the isolation region 102. The first coil 104 and the second coil 106 may be magnetically coupled to each other in a lateral direction. Thus, the first coil 104 and the second coil 106 form a lateral transformer 108. The first coil 104 may be electrically coupled to first circuitry (e.g., transmitter circuitry, receiver circuitry, or transceiver circuitry) of the voltage domain A and may be isolated from the voltage domain B. The second coil 106 may be electrically coupled to second circuitry (e.g., transmitter circuitry, receiver circuitry, or transceiver circuitry) of the voltage domain B and may be isolated from the voltage domain A. For example, the first coil 104 may be arranged at an edge region of voltage domain A and the second coil 106 may be arranged at an edge region of voltage domain B. The first coil 104 and the second coil 106 may have a same number of turns or a different number of turns in accordance with a desired transmission ratio of the lateral transformer 108. The first coil 104 and the second coil 106 may be arranged in an insulator layer (not illustrated in FIG. 1A) that is arranged over a circuit substrate (e.g., a semiconductor layer) that includes the first circuitry and the second circuity. Thus, the first coil 104 may be arranged over the voltage domain A and the second coil 106 may be arranged over the voltage domain B.

In some implementations, the first coil 104 may be a primary coil that is coupled to an input voltage and the second coil 106 may be a secondary coil that is configured to generate an output voltage based on the magnetic coupling of the first coil 104 and the second coil 106. In some implementations, the second coil 106 may be a primary coil that is coupled to an input voltage and the first coil 104 may be a secondary coil that is configured to generate an output voltage based on the magnetic coupling of the first coil 104 and the second coil 106. For example, the first coil 104 and the second coil 106 may be used for bidirectional energy transfer (e.g., for bidirectional communications).

In some implementations, the lateral transformer 108 may be used to transmit power signals in order to transfer power from the primary coil (e.g., the first coil 104) to the secondary coil (e.g., the second coil 106) in a DC-DC power converter application. For example, the lateral transformer 108 may be configured to supply power from a primary side to a secondary side of the lateral transformer 108, where the power is used for operating components of the circuitry provided on the secondary side.

In some implementations, the isolation region 102 may laterally encircle voltage domain B to laterally separate the two voltage domains. In other words, the voltage domain B may be laterally embedded in the isolation region 102.

As indicated above, FIG. 1A is provided as an example. Other examples may differ from what is described with regard to FIG. 1A.

FIG. 1B illustrates a multi-voltage domain device 100B according to one or more implementations. The multi-voltage domain device 100B includes a semiconductor substrate 100 (e.g., a handle wafer), a buried oxide (BOX) layer 112 formed on the semiconductor substrate 110, and a semiconductor layer 114 formed on the BOX layer 112. For example, the BOX layer 112 may be formed in a silicon-on-insulator (SOI) wafer that includes the semiconductor substrate 110 and the semiconductor layer 114 arranged at opposite sides of the BOX layer 112. The BOX layer 112 may alternatively be referred to as a wafer insulator layer. It will be appreciated that other types of semiconductor substrate/insulator layer structures may also be used.

In some implementations, the semiconductor layer 114 may be replaced with a different type of circuit substrate, such as a printed circuit board (PCB), that includes alternating conductive layers and insulating layers. In this case, the semiconductor substrate 110 and the BOX layer 112 may optionally not be provided, since the PCB is sturdy and isolating on its own, which may render the semiconductor substrate 110 and the BOX layer 112 as not needed. The coils 104 and 106 may be formed using conductive traces and conductive vias in the PCB.

The multi-voltage domain device 100B includes the voltage domain A formed in the semiconductor layer 114 (e.g., a silicon layer), the voltage domain B formed in the semiconductor layer 114, and a voltage domain C formed in the semiconductor layer 114, with each voltage domain having corresponding circuitry integrated in the semiconductor layer 114. For example, the voltage domain A may include first circuitry, the voltage domain B may include second circuity, and the voltage domain C may include third circuitry, where the first circuitry, the second circuitry, and the third circuitry are galvanically isolated from each other. Thus, the semiconductor layer 114 may be a circuit substrate in which functional circuit components and devices are formed (e.g., integrated within) for each voltage domain. In other words, the multi-voltage domain device 100B may be a monolithic device that includes multiple voltage domains that are isolated from each other by one or more isolation regions. Additionally, multiple lateral transformers may be provided monolithically in the multi-voltage domain device 100B.

In some implementations, the voltage domain A may be formed as a first island that is surrounded by a first isolation region 102-1 (e.g., a first DTI barrier of one or more DTI trenches), and the voltage domain B may be formed as a second island that is surrounded by a second isolation region 102-2 (e.g., a first DTI barrier of one or more DTI trenches). Thus, the voltage domain A, the voltage domain B, and the voltage domain C are electrically isolated from each other in a lateral plane of the semiconductor layer 114 by the first isolation region 102-1 and the second isolation region 102-2.

One or more lateral transformers 108-1, 108-2, and 108-3 may be arranged in an insulator layer (not illustrated in FIG. 1B) that is arranged over the semiconductor layer 114 that includes the first circuitry, the second circuity, and the third circuitry. In some implementations, the insulator layer may be a BEOL layer stack that is formed by a BEOL process. The insulator layer may include a plurality of metal layers and vias formed in a stack of insulator layers (e.g., insulator sub-layers), such as oxide layers. In particular, the metal layers and vias may be embedded in and/or alternated with one or more insulator sub-layers in a vertical direction to form the BEOL layer stack. The metal layers and vias may be used to form the coils of the lateral transformers 108-1, 108-2, and 108-3 and to form conductive connections to respective circuitry located in the semiconductor layer 114. The BEOL layer stack may be formed on the semiconductor layer 114.

The lateral transformer 108-1 may include a pair of coils, similar to coils 104 and 106, used for transferring energy between voltage domain A and voltage domain C (e.g., for transmitting signals between voltage domain A and voltage domain C). The lateral transformer 108-2 may include a pair of coils, similar to coils 104 and 106, used for transferring energy between voltage domain A and voltage domain B (e.g., for transmitting signals between voltage domain A and voltage domain B). The lateral transformer 108-3 may include a pair of coils, similar to coils 104 and 106, used for transferring energy between voltage domain B and voltage domain C (e.g., for transmitting signals between voltage domain B and voltage domain C).

As indicated above, FIG. 1B is provided as an example. Other examples may differ from what is described with regard to FIG. 1B.

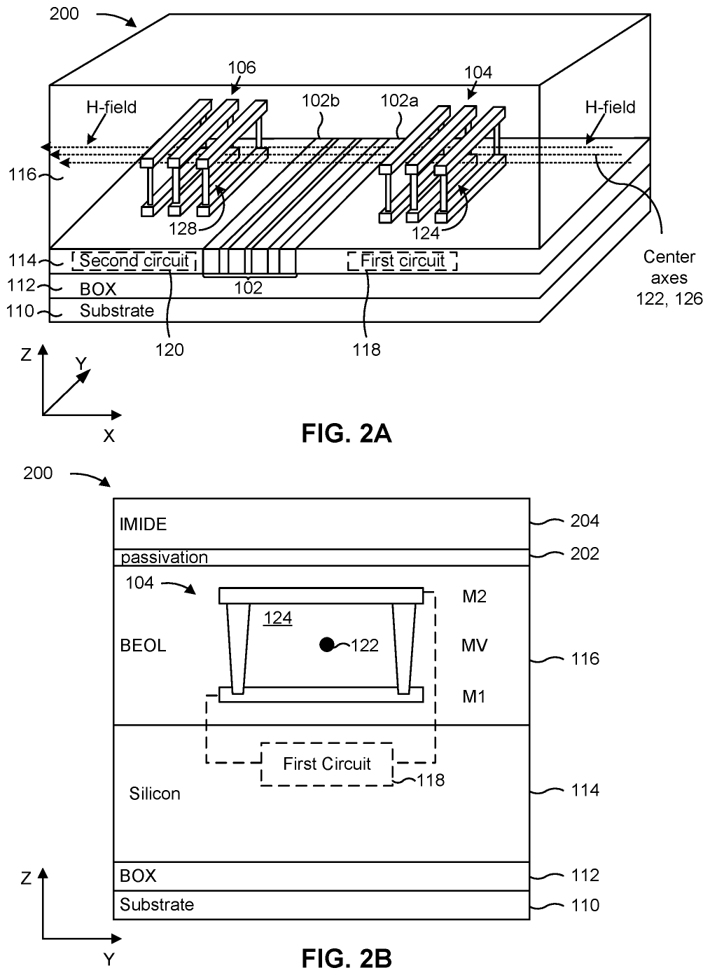

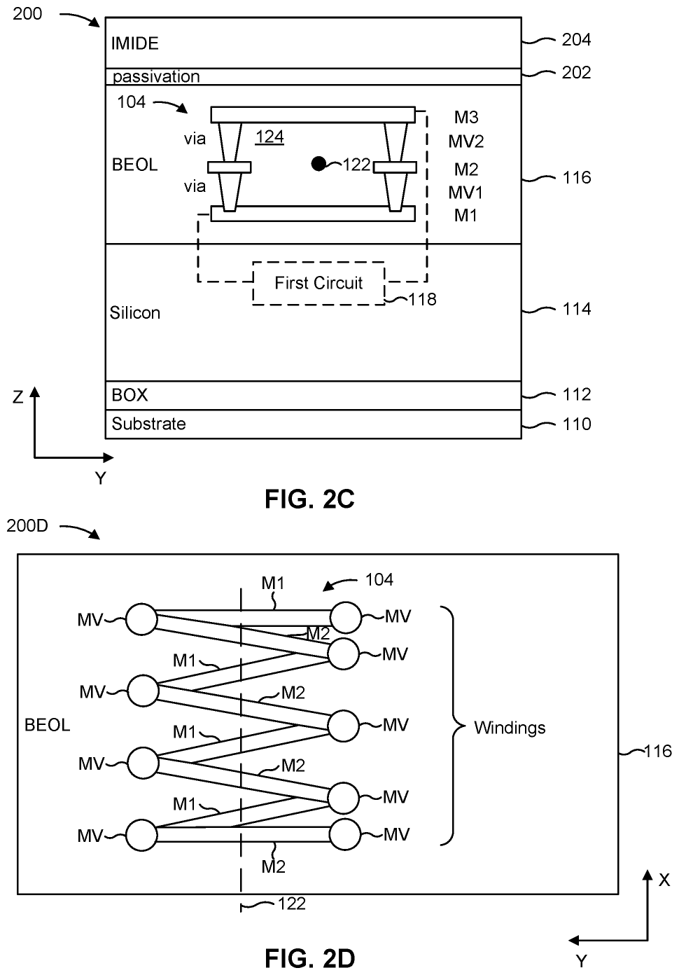

FIG. 2A illustrates a multi-voltage domain device 200 according to one or more implementations. The multi-voltage domain device 200 includes the semiconductor substrate 110 (e.g., a handle wafer), the BOX layer 112 formed on the semiconductor substrate 110, the semiconductor layer 114 formed on the BOX layer 112, and an insulator layer 116 formed on the semiconductor layer 114. In some implementations, the insulator layer 116 may be a BEOL layer stack that includes a pattern of insulator sub-layers and metal layers and vias. Multiple metal layers and vias may be deposited within the insulator layer 116 to form the coils 104 and 106 of a lateral transformer. Thus, the insulator layer 116 may be a stack-insulator layer comprising a plurality of sub-insulator layers. The conductive layers and vias (e.g., metal layers and vias) may be integrated within the sub-insulator layers of the stack-insulator layer.

The semiconductor layer 114 may include a first circuit 118 configured to operate in a first voltage domain (e.g., voltage domain A) and a second circuit 120 configured to operate in a second voltage domain (e.g., voltage domain B). For example, the first circuit 118 may include circuitry (e.g., pulse width modulation (PWM) logic and an LV gate driver) configured to drive a low-side transistor of a half-bridge and the second circuit 120 may include circuitry (e.g., an HV gate driver) configured to drive a high-side transistor of the half-bridge. The half-bridge may be used to generate a load current for driving a load. The first circuit 118 may also include transmitter circuitry or transceiver circuitry used to transmit signals (e.g., communication signals or power signals), from the first coil 104 to the second coil 106. For example, the transmission circuitry may be used to transmit control signals to the HV gate driver used for driving the high-side transistor. Thus, the second circuit 120 may also include receiver circuitry or transceiver circuitry used to receive and process the signals from the second coil 106 for controlling the high-side transistor. The second circuit 120 may also be configured to transmit feedback signals (e.g., communication signals or power signals) regarding the high-side transistor from the second coil 106 to the first coil 104, which may be received and processed by the first circuit 118.

The semiconductor layer 114 also includes the isolation region 102 that electrically isolates the first circuit 118 (e.g., the first voltage domain) and the second circuit 120 (e.g., the second voltage domain). Thus, the signals originating from the first circuit 118 and/or the second circuit 120 may be transmitted over the isolation region 102 using the coils 104 and 106. The isolation region 102 may include one or more DTI barriers (e.g., DTI barriers 102a and 102b) used to isolate the first voltage domain from the second voltage domain. Each of the DTI barriers of the isolation region 102 may extend vertically from an upper main surface of the semiconductor layer 114 to an upper main surface of the BOX layer 2 (e.g., to a lower main surface of the semiconductor layer 114). In this example, the lower main surface of the semiconductor layer 114 is arranged at the upper main surface of the BOX layer 2. Thus, each of the DTI barriers of the isolation region 102 may be a trench delimited by semiconductor material of the semiconductor layer 114 that forms the sidewalls of each trench. Each DTI barrier may be structured in a manner to provide lateral isolation within the semiconductor layer 114, practically defining the isolation region 102 within the semiconductor layer 114. Therefore, the minimum number of DTI barriers may be one. Each DTI barrier may be at least partially filled with a same or a different insulating material than an insulating material used for the BOX layer 112 and/or the insulator layer 116. For example, each DTI barrier may be at least partially filled with an insulator material and/or polysilicon to fill the trench.

The first coil 104 and the second coil 106 are arranged in the insulator layer 116. For example, the first coil 104 may include a first plurality of conductive layers and a first plurality of conductive vias (e.g., metal layers and metal vias) integrated in the insulator layer 116. The conductive vias of the first coil 104 may extend vertically within the insulator layer 116 to connect the different conductive layers of the first coil 104. In some implementations, conductive vias of the first coil 104 may extend laterally within the insulator layer 116 to connect different conductive segments of a same conductive layer. Additionally, the second coil 106 may include a second plurality of conductive layers and a second plurality of conductive vias (e.g., metal layers and metal vias) integrated in the insulator layer 116. The conductive vias of the second coil 106 may extend vertically within the insulator layer 116 to connect the conductive layers of the second coil 106. In some implementations, conductive vias of the second coil 106 may extend laterally within the insulator layer 116 to connect different conductive segments of a same conductive layer. Thus, the first coil 104 and the second coil 106 are encapsulated by the insulator material of the insulator layer 116. Therefore, the first coil 104 and the second coil 106 are laterally separated from each other in the lateral direction by an insulator material of the insulator layer 116.

The first coil 104 is electrically coupled to the first circuit 118 and the second coil 106 is electrically coupled to the second circuit 120, for example, by additional conductive vias and/or additional conductive layers. For example, electrical contacts of the first coil 104 may be coupled to respective terminals of a communication circuit located in voltage domain A that is configured to either excite the first coil 104 for data transmission, or receive (i.e., sample) a data transmission from the first coil 104. Electrical contacts of the second coil 106 may be coupled to respective terminals of a communication circuit located in voltage domain B that is configured to either excite the second coil 106 for data transmission, or receive (i.e., sample) a data transmission from the second coil 106.

The first coil 104 may be arranged vertically over a first region of the semiconductor layer 114 corresponding to the first voltage domain. The second coil 106 may be arranged vertically over a second region of the semiconductor layer 114 corresponding to the second voltage domain.

In addition, in some cases at least one of the coils 104 and 106 may cross, partially or fully, over the isolation region 102 to achieve better magnetic coupling between the coils 104 and 106. A coil that extends over the isolation region 102 may be referred to as a “cross-over” coil. However, terminals of the cross-over coil remain fully within the coil's designated voltage domain. This simultaneously allows to maintain a desired degree of isolation between voltage domains while achieving better magnetic coupling between the coils 104 and 106.

For example, one or more metal layers of the first coil 104 may laterally extend from voltage domain A partially over the isolation region 102 so that part of first coil 104 is vertically overlapping with one or more DTI barriers of the isolation region 102. However, the terminals of the coil 104 remain laterally within voltage domain A. Thus, the first coil 104 does not have any direct electrical contact to voltage domain B and remains isolated from voltage domain B.

Additionally, or alternatively, one or more metal layers of the second coil 106 may laterally extend from voltage domain B partially over the isolation region 102 so that part of the second coil 106 is vertically overlapping with one or more DTI barriers of the isolation region 102. However, the terminals of the second coil 106 remain laterally within voltage domain B. Thus, the second coil 106 does not have any direct electrical contact to voltage domain A and remains isolated from voltage domain A.

It is noted that it is possible that both coils 104 and 106 partially cross over the isolation region 102. This would simultaneously allow to maintain a higher degree of isolation between voltage domains A and B while achieving better magnetic coupling between the coils 104 and 106.

The first coil 104 has a first center axis 122 around which first windings of the first coil 104 are wound. The first center axis 122 extends parallel to a lateral direction (e.g., an x-direction), which in parallel to the upper and lower main surfaces of the semiconductor layer 114. The first coil 104 produces, at least in part, a magnetic field H (e.g., H-field) that is induced by a flow of current through the first windings of the first coil 104. Part of the magnetic field H, represented by magnetic field lines, extends along and/or in parallel to the first center axis 122. Additionally, the first windings define a first core area 124 of the first coil 104 that laterally extends along the first center axis 122. The first core area 124 is an internal area of the first coil 104 that is encircled by the first windings.

The second coil 106 has a second center axis 126 around which second windings of the second coil 106 are wound. The second center axis 126 extends parallel to the lateral direction (e.g., the x-direction). The second coil 106 produces, at least in part, the magnetic field H that is induced by a flow of current through the second windings of the second coil 106. Part of the magnetic field H, represented by the magnetic field lines, extends along and/or in parallel to the second center axis 126. The first coil 104 and the second coil 106 are magnetically coupled together by respective magnetic fields H. Additionally, the second windings define a second core area 128 of the second coil 106 that laterally extends along the second center axis 126. The second core area 128 is an internal area of the second coil 106 that is encircled by the second windings.

In order to improve the magnetic coupling of the first coil 104 and the second coil 106 and the transformer efficiency of the lateral transformer, the first core area 124 is at least partially aligned with the second core area 128 in the lateral direction (e.g., the x-direction). Thus, the first coil 104 and the second coil 106 are magnetically coupled to each other in the lateral direction based on an alignment of the first core area 124 with the second core area 128. In some implementations, the first core area 124 and the second core area 128 completely overlap in the lateral direction. In some implementations, the first center axis 122 and the second center axis 126 are aligned with each other to optimize the magnetic coupling of the first coil 104 and the second coil 106. In other words, the first center axis 122 and the second center axis 126 are collinear. Thus, the first coil 104 and the second coil 106 may be magnetically coupled to each other in the lateral direction based on an alignment of the first center axis 122 with the second center axis 126.

As indicated above, FIG. 2A is provided as an example. Other examples may differ from what is described with regard to FIG. 2A. The number and arrangement of devices and components shown in FIG. 2A are provided as an example. In practice, there may be additional devices or components, fewer devices or components, different devices or components, or differently arranged devices or components than those shown in FIG. 2A. For example, additional layers, such a passivation layer and an imide layer may be arranged on the insulator layer 116.

FIG. 2B illustrates a side view of the multi-voltage domain device 200 according to one or more implementations. The multi-voltage domain device 200 includes the semiconductor substrate 110, the BOX layer 112 formed on the semiconductor substrate 110, the semiconductor layer 114 formed on the BOX layer 112, and the insulator layer 116 formed on the semiconductor layer 114. The insulator layer 116 may be a stack-insulator layer comprising a plurality of sub-insulator layers. The conductive layers and vias (e.g., metal layers and vias) may be integrated within the sub-insulator layers of the stack-insulator layer. In some implementations, the multi-voltage domain device 200B may also include a passivation layer 202 and an imide layer 204 arranged on the insulator layer 116. The passivation layer 202 and an imide layer 204 may be used to provide protection to the underlying layers and components of the multi-voltage domain device 200.

In FIG. 2B, the first coil 104 is visible. The first coil 104 may be formed by metal layers M1 and M2 that are vertically separated by the insulator material of the insulator layer 116. In addition, vertical vias MV may be used to connect corresponding portions of the metal layers M1 and M2 in order to form the first windings of the first coil 104. The first windings define the first core area 124 of the first coil 104 that laterally extends along the first center axis 122. The first windings of the first coil 104 spiral horizontally through the insulator layer 116 in a direction of the first center axis 122. The second windings of the second coil 106 may be formed in a similar manner in order to spiral horizontally through the insulator layer 116 in the direction of the second center axis 126.

The first circuit 118 may be electrically coupled to two terminals of the first coil 104 in order to either excite the first coil 104 for signal transmission, or receive (e.g., sample) a signal transmission from the first coil 104.

As indicated above, FIG. 2B is provided as an example. Other examples may differ from what is described with regard to FIG. 2B.

FIG. 2C illustrates a side view of the multi-voltage domain device 200 according to one or more implementations. The multi-voltage domain device 200 includes the semiconductor substrate 110, the BOX layer 112 formed on the semiconductor substrate 110, the semiconductor layer 114 formed on the BOX layer 112, and the insulator layer 116 formed on the semiconductor layer 114. The insulator layer 116 may be a stack-insulator layer comprising a plurality of sub-insulator layers. The conductive layers and vias (e.g., metal layers and vias) may be integrated within the sub-insulator layers of the stack-insulator layer. In some implementations, the multi-voltage domain device 200C may also include the passivation layer 202 and the imide layer 204 arranged on the insulator layer 116.

In FIG. 2C, the first coil 104 is visible. The first coil 104 may be formed by metal layers M1, M2, and M3 that are vertically separated by the insulator material of the insulator layer 116. In addition, vertical vias MV1 may be used to connect corresponding portions of the metal layers M1 and M2 and vertical vias MV2 may be used to connect corresponding portions of the metal layers M2 and M3 in order to form the first windings of the first coil 104. The first windings of the first coil 104 spiral horizontally through the insulator layer 116 in a direction of the first center axis 122. The second windings of the second coil 106 may be formed in a similar manner in order to spiral horizontally through the insulator layer 116 in the direction of the second center axis 126. Accordingly, three or more metal layers and corresponding vertical vias may be used to form the coils 104 and 106.

As indicated above, FIG. 2C is provided as an example. Other examples may differ from what is described with regard to FIG. 2C.

FIG. 2D illustrates a top view of a portion 200D of a multi-voltage domain device according to one or more implementations. For example, the portion 200D may correspond to a portion of the multi-voltage domain device 200. FIG. 2D, the first coil 104 is visible. Metal layers M1 and M2 may be coupled in an alternating pattern by vertical vias MV to form the first windings of the first coil 104. The first windings of the first coil 104 spiral horizontally through the insulator layer 116 in a direction of the first center axis 122. The second windings of the second coil 106 may be formed in a similar manner in order to spiral horizontally through the insulator layer 116 in the direction of the second center axis 126.

As indicated above, FIG. 2D is provided as an example. Other examples may differ from what is described with regard to FIG. 2D.

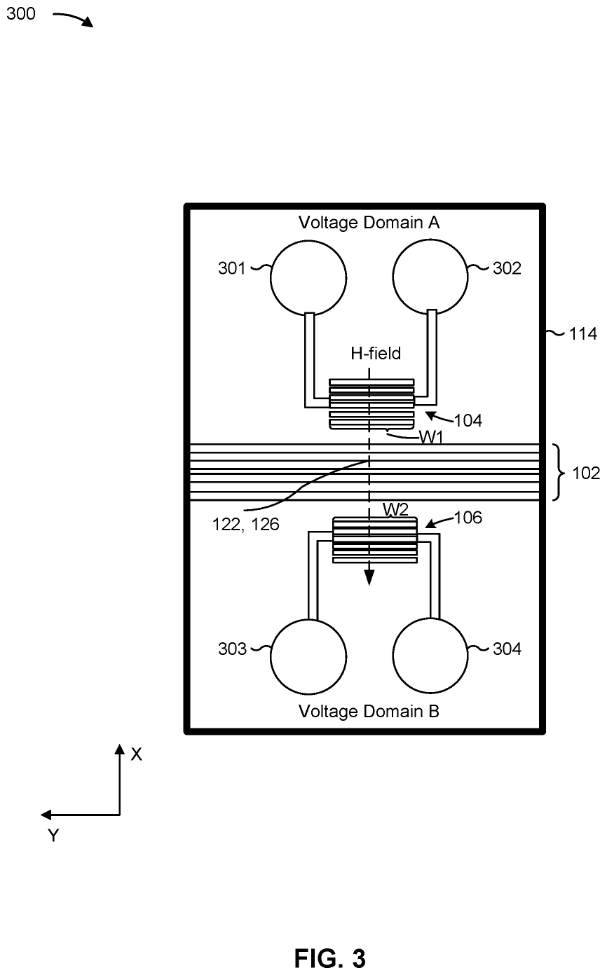

FIG. 3 illustrates a top view of a lateral transformer circuit 300 according to one or more implementations. The lateral transformer circuit 300 may be formed over the semiconductor layer 114 as similarly described in connection with FIG. 2A. The lateral transformer circuit 300 may include the first coil 104 formed over and electrically coupled to the voltage domain A of the semiconductor layer 114. For example, terminals 301 and 302 of the first coil 104 may be coupled to a first circuit (e.g., the first circuit 118) integrated in the semiconductor layer 114. Additionally, the lateral transformer circuit 300 may include the second coil 106 formed over and electrically coupled to the voltage domain B of the semiconductor layer 114. For example, terminals 303 and 304 of the second coil 106 may be coupled to a second circuit (e.g., the second circuit 120) integrated in the semiconductor layer 114. Thus, signals may be transmitted over the isolation region 102.

In some implementations, the first coil 104 and the second coil 106 may be aligned with each other such that the first center axis 122 and the second center axis 126 are collinear. The magnetic field H extends along the first center axis 122 and the second center axis 126. As a result, a magnetic coupling of the first coil 104 and the second coil 106 may be enhanced. Additionally, the first coil 104 and the second coil 106 may have a same or substantially similar dimensions such that the core areas of the first coil 104 and the second coil 106 fully overlap or substantially overlap. For example, a coil width W1 of the first coil 104 and a coil width W2 of the second coil 106 may be equal or substantially equal. The coil width W1 of the first coil 104 may be uniform or substantially uniform throughout a length of the first coil 104. Moreover, the coil width W2 of the second coil 106 may be uniform or substantially uniform throughout a length of the second coil 106.

As indicated above, FIG. 3 is provided as an example. Other examples may differ from what is described with regard to FIG. 3.

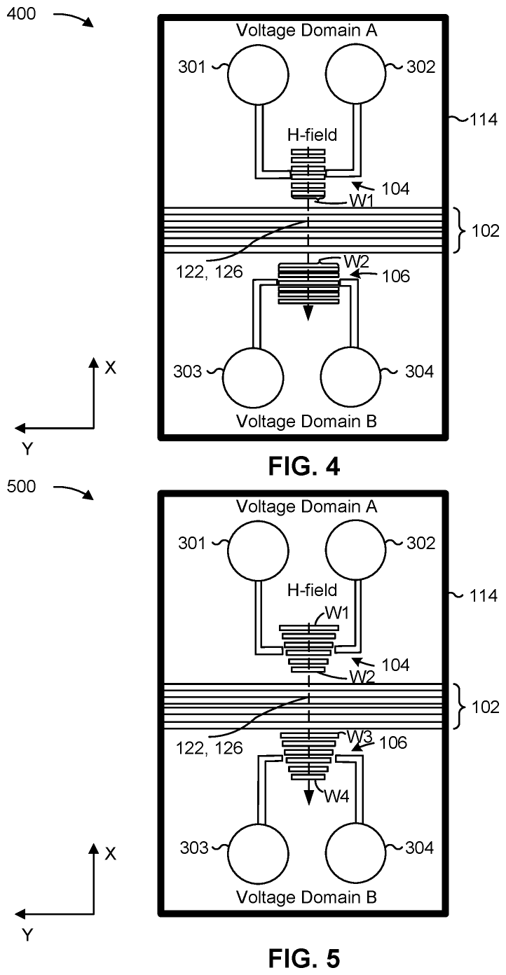

FIG. 4 illustrates a top view of a lateral transformer circuit 400 according to one or more implementations. The lateral transformer circuit 400 may be similar to the lateral transformer circuit 300 described in connection with FIG. 3, with the exception that the coil width W1 of the first coil 104 may be different from the coil width W2 of the second coil 106. In some implementations, the transmitting coil (e.g., the first coil 104) may have a smaller width in order to generate a more focused or steered magnetic field H to be received by the receiving coil (e.g., the second coil 106). Additionally, the larger width of the receiving coil (e.g., the second coil 106) may enable better reception of the magnetic field H from the transmitting coil. As a result, a magnetic coupling factor of the first coil 104 and the second coil 106 may be increased.

The coil width W1 of the first coil 104 may be uniform or substantially uniform throughout a length of the first coil 104. Moreover, the coil width W2 of the second coil 106 may be uniform or substantially uniform throughout a length of the second coil 106.

As indicated above, FIG. 4 is provided as an example. Other examples may differ from what is described with regard to FIG. 4.

FIG. 5 illustrates a top view of a lateral transformer circuit 500 according to one or more implementations. The lateral transformer circuit 500 may be similar to the lateral transformer circuit 300 described in connection with FIG. 3, with the exception that one or both of the first coil 104 and the second coil 106 may be tapered coils having tapered coil widths that change in the lateral direction (e.g., the x-direction). In other words, one or both of the first coil 104 and the second coil 106 may have a funnel design used to funnel the magnetic field lines through the core areas 124 and 128 of the first coil 104 and the second coil 106, respectively. For example, the first coil 104 may have a first tapered coil width that changes in the lateral direction from a first coil width W1 at a first coil end of the first coil 104 to a second coil width W2 at a second coil end of the first coil 104, where the second coil end may correspond to a transmission side of the first coil 104 that is located more proximate to the isolation region 102 than the first coil end. The first coil width W1 may be larger than the second coil width W2 in order to generate a more focused or steered magnetic field H.

Alternatively, or additionally, the second coil 106 may have a second tapered coil width that changes in the lateral direction from a third coil width W3 at a third coil end of the second coil 106 to a fourth coil width W4 at a fourth coil end of the second coil 106, where the third coil end may correspond to a receiving side of the second coil 106 that is located more proximate to the isolation region 102 than the fourth coil end. The third coil width W3 may be larger than the fourth coil width W4 in order to enable better reception of the magnetic field H from the transmitting coil. Thus, a distance between the second coil end and the third coil end is a minimum distance between the first coil 104 and the second coil 106 in the lateral direction.

As indicated above, FIG. 5 is provided as an example. Other examples may differ from what is described with regard to FIG. 5.

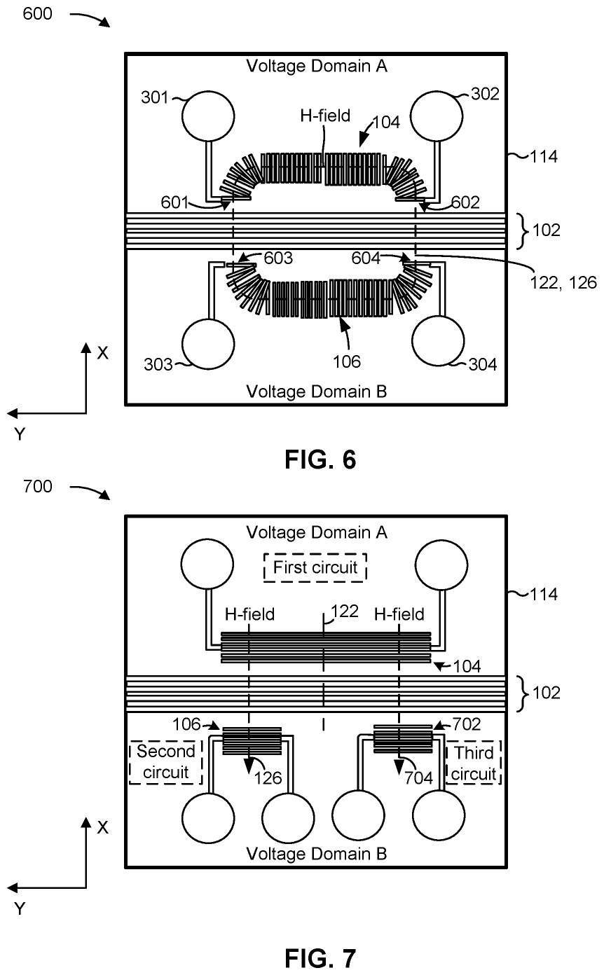

FIG. 6 illustrates a top view of a lateral transformer circuit 600 according to one or more implementations. The lateral transformer circuit 600 includes two U-shaped coils, where the first coil 104 has a first U-shape and the second coil 106 has a second U-shape. A geometry of the first coil 104 may be a mirrored representation of a geometry of the second coil 106 across the isolation region. In other word, the first U-shape may be in inverted representation of the second U-shape.

The first coil 104 may have a first coil end 601 and a second coil end 602. The second coil 106 may have a third coil end 603 and a fourth coil end 604. The third coil end 603 that may be aligned with the first coil end 601 in the lateral direction, and the fourth coil end 604 that may be aligned with the second coil end 602 in the lateral direction. For example, the center axes 122 and 126 may be aligned with each other as the center axes 122 and 126 extend over the isolation region 102. For example, the first coil may have a first coil opening at the first coil end 601 and a second coil opening at the second coil end 602, and the second coil may have a third coil opening at the third coil end 603 and a fourth coil opening at the fourth coil end 604. The first coil opening may face the third coil opening, and vice versa. The second coil opening faces the fourth coil opening, and vice versa.

The first U-shape and the second U-shape may be used to reduce stray magnetic fields by steering the magnetic field H towards the opposing coil and may enable a gap between coil openings to be reduced. Additionally, the first U-shape and the second U-shape may reduce an influence of stray magnetic fields on outer circuitry. Accordingly, the alignment of the first U-shape with the second U-shape may improve the magnetic coupling between the first coil 104 and the second coil 106.

As indicated above, FIG. 6 is provided as an example. Other examples may differ from what is described with regard to FIG. 6.

FIG. 7 illustrates a top view of a lateral transformer circuit 700 according to one or more implementations. In this example, a first region of the semiconductor layer 114 (e.g., voltage domain A) includes first circuitry and a second region of the semiconductor layer 114 (e.g., voltage domain B) includes second circuitry and third circuitry. The isolation region 102 electrically isolates the first region and the second region in the lateral direction (e.g., the x-direction) in order to electrically isolate the first circuitry from the second circuitry and to electrically isolate the first circuitry from the third circuitry. Each circuitry of the first circuity, second circuitry, and the third circuitry may include a respective communication circuit for transmitting and/or receiving signals by a respective coil.

The lateral transformer circuit 700 includes the first coil 104 and the second coil 106 arranged in the insulator layer 116 (not shown), as described above. Thus, the first coil 104 and the second coil 106 are electrically coupled to the first circuity and the second circuitry. Additionally, the lateral transformer circuit 700 includes a third coil 702 arranged in the insulator layer 116 and electrically coupled to the third circuity.

The first coil 104 has a first center axis 122 around which first windings of the first coil 104 are wound. The first windings define a first core area of the first coil 104 that extends along the first center axis. The second coil 106 has the second center axis 126 around which second windings of the second coil 106 are wound. The second windings define a second core area of the second coil 106 that extends along the second center axis 126. The third coil 702 has a third center axis 704 around which third windings of the third coil 702 are wound. The third windings define a third core area of the third coil 702 that extends along the third center axis 704. The second core area of the second coil 106 is at least partially aligned with the first core area of the first coil 104 in the lateral direction. In addition, the third core area of the third coil 702 is at least partially aligned with the first core area of the first coil 104 in the lateral direction. In other words, the second center axis 126 and the third center axis 704 extend through the first core area of the first coil 104.

As a result, the first coil 104 and the second coil 106 are magnetically coupled to each other in the lateral direction based on an alignment of the first core area with the second core area, and the first coil 104 and the third coil 702 are magnetically coupled to each other in the lateral direction based on an alignment of the first core area with the third core area. For example, the magnetic field H generate by the first coil 104 is coupled to the second coil 106 and the third coil 702 along the second center axis 126 and the third center axis 704, respectively. Thus, the first coil 104 may be coupled to multiple secondary coils.

In some implementations, wherein the second coil 106 has a first quantity of windings and the third coil 702 has a second quantity of windings that is different from the first quantity of windings. As a result, the first and the second coil have a transmission ration that is different from a transmission ratio of the first and the third coil. This configuration may be used when the second circuit and the third circuit use different supply voltages (e.g., different HV voltage levels). Thus, the second coil 106 and the third coil 702 may provide different output voltages for the second circuit and the third circuit, respectively.

As indicated above, FIG. 7 is provided as an example. Other examples may differ from what is described with regard to FIG. 7.

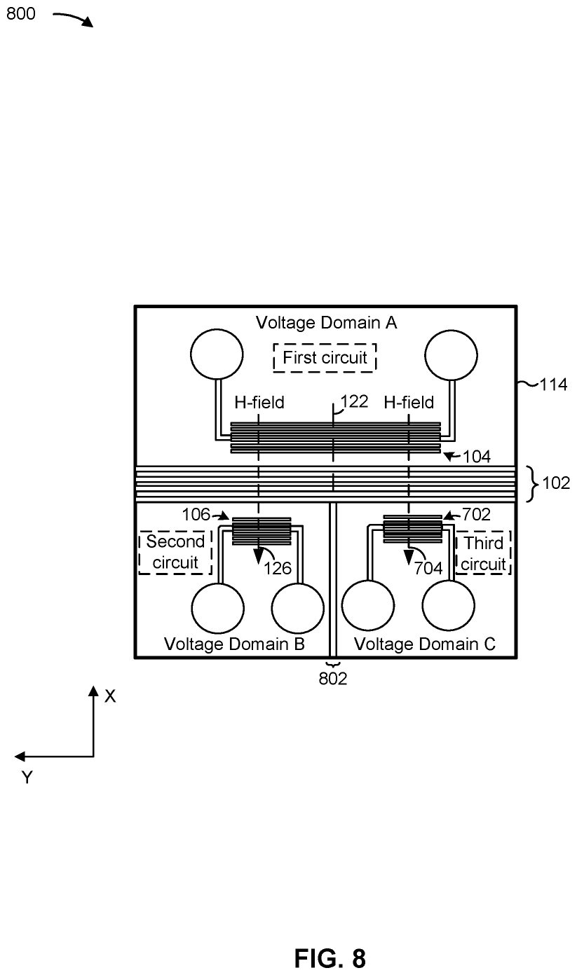

FIG. 8 illustrates a top view of a lateral transformer circuit 800 according to one or more implementations. The lateral transformer circuit 800 may be similar to the lateral transformer circuit 700 described in connection with FIG. 7, with the exception that the third region (e.g., voltage domain C) is also electrically isolated from the second region (e.g., the voltage domain B) by an isolation region 802, which may include one or more DTI barriers formed in the semiconductor layer 114. In some implementations, the isolation region 802 may be an extension of the isolation region 102. Thus, the semiconductor layer 114 includes at least one isolation region (e.g., isolation regions 102 and 802) that electrically isolates the first region and the second region in a first lateral direction (e.g., the x-direction) in order to electrically isolate the first circuitry and the second circuitry, electrically isolates the first region and the third region in the first lateral direction (e.g., the x-direction) in order to electrically isolate the first circuitry and the third circuitry, and electrically isolates the second region and the third region in a second lateral direction (e.g., the y-direction) in order to electrically isolate the second circuitry and the third circuitry. Thus, three isolated regions may be provided that may have different voltage domains, same voltage domains that require isolation, or a combination of different voltage domains and same voltage domains that require isolation.

As indicated above, FIG. 8 is provided as an example. Other examples may differ from what is described with regard to FIG. 8.

The following provides an overview of some Aspects of the present disclosure:

Aspect 1: A multi-voltage domain device, comprising: a circuit substrate comprising a first main surface and a second main surface arranged opposite to the first main surface, wherein the circuit substrate comprises: a first region comprising first circuitry that operates in a first voltage domain, a second region comprising second circuitry that operates in a second voltage domain, and an isolation region that electrically isolates the first region and the second region in a lateral direction that extends parallel to the first main surface and the second main surface; an insulator layer arranged on the first main surface of the circuit substrate; a first coil arranged in the insulator layer, wherein the first coil is electrically coupled to the first circuitry and is isolated from the second region, wherein the first coil has a first center axis around which first windings of the first coil are wound, and wherein the first center axis extends parallel to the lateral direction; and a second coil arranged in the insulator layer and laterally separated from the first coil in the lateral direction by an insulator material of the insulator layer, wherein the second coil is electrically coupled to the second circuitry and is isolated from the first region, wherein the second coil has a second center axis around which second windings of the second coil are wound, and wherein the second center axis extends parallel to the lateral direction and is aligned with the first center axis, wherein the first coil and the second coil are magnetically coupled to each other in the lateral direction based on an alignment of the first center axis with the second center axis.

Aspect 2: The multi-voltage domain device of Aspect 1, wherein the first center axis is collinear with a first magnetic axis of the first coil and the second center axis is collinear with a second magnetic axis of the second coil.

Aspect 3: The multi-voltage domain device of any of Aspects 1-2, wherein the insulator layer is a stack-insulator layer comprising a plurality of sub-insulator layers, wherein the first coil comprises a first plurality of conductive layers and a first plurality of conductive vias integrated in the insulator layer, and wherein the second coil comprises a second plurality of conductive layers and a second plurality of conductive vias integrated in the insulator layer.

Aspect 4: The multi-voltage domain device of Aspect 3, wherein the first plurality of conductive vias extend vertically between first plurality of conductive layers, and the second plurality of conductive vias extend vertically between second plurality of conductive layers.

Aspect 5: The multi-voltage domain device of any of Aspects 1-4, wherein the first coil and the second coil are encapsulated by the insulator material of the insulator layer.

Aspect 6: The multi-voltage domain device of any of Aspects 1-5, wherein the first coil has a first coil width, and wherein the second coil has a second coil width that is different from the first coil width.

Aspect 7: The multi-voltage domain device of Aspect 6, wherein the first coil width is uniform or substantially uniform throughout the first coil, and wherein the second coil width is uniform or substantially uniform throughout the second coil.

Aspect 8: The multi-voltage domain device of any of Aspects 1-7, wherein at least one of the first coil or the second coil is a tapered coil having a respective tapered coil width that changes in the lateral direction, and/or wherein the first coil has a first tapered coil width that changes in the lateral direction from a first coil width at a first coil end of the first coil to a second coil width at a second coil end of the first coil, and/or wherein the second coil has a second tapered coil width that changes in the lateral direction from a third coil width at a third coil end of the second coil to a fourth coil width at a fourth coil end of the second coil.

Aspect 9: The multi-voltage domain device of Aspect 8, wherein the first coil width is larger than the second coil width, wherein the third coil width is larger than the fourth coil width, and wherein a distance between the second coil end and the third coil end is a minimum distance between the first coil and the second coil in the lateral direction.

Aspect 10: The multi-voltage domain device of any of Aspects 1-9, wherein the first coil has first U-shape comprising a first coil end and a second coil end, wherein the second coil has second U-shape comprising a third coil end and a fourth coil end, wherein the first coil end of the first coil is aligned with the third coil end of the second coil across the isolation region, and wherein the second coil end of the first coil is aligned with the fourth coil end of the second coil across the isolation region.

Aspect 11: The multi-voltage domain device of Aspect 10, wherein the first coil has a first coil opening at the first coil end and a second coil opening at the second coil end, wherein the second coil has a third coil opening at the third coil end and a fourth coil opening at the fourth coil end, wherein the first coil opening faces the third coil opening, wherein the third coil opening faces the first coil opening, wherein the second coil opening faces the fourth coil opening, and wherein the fourth coil opening faces the second coil opening.

Aspect 12: The multi-voltage domain device of Aspect 10, wherein a first geometry of the first coil is a mirrored representation of a second geometry of the second coil across the isolation region.

Aspect 13: The multi-voltage domain device of any of Aspects 1-12, wherein the isolation region comprises one or more trench isolation barriers, and wherein each of the one or more trench isolation barriers extends vertically from the first main surface to the second main surface.

Aspect 14: The multi-voltage domain device of any of Aspects 1-13, wherein the first coil comprises at least two first terminals that are arranged vertically over the first region and are electrically coupled to the first circuitry, and wherein the second coil comprises at least two second terminals that are arranged vertically over the second region and are electrically coupled to the second circuitry.

Aspect 15: The multi-voltage domain device of any of Aspects 1-14, wherein the first coil and the second coil are configured to utilize a magnetic coupling to transmit communication signals or power signals between the first circuitry and the second circuitry, over the isolation region.

Aspect 16: The multi-voltage domain device of any of Aspects 1-15, wherein the circuit substrate is a semiconductor substrate.

Aspect 17: The multi-voltage domain device of any of Aspects 1-16, further comprising: a wafer insulator layer comprising a third main surface; wherein the second main surface of the circuit substrate is arranged at the third main surface of the wafer insulator layer, and wherein the isolation region includes at least one trench isolation barrier that extends vertically from the first main surface to the third main surface.

Aspect 18: The multi-voltage domain device of Aspect 17, further comprising a silicon-on-insulator (SOI) wafer comprising the circuit substrate and the wafer insulator layer.

Aspect 19: The multi-voltage domain device of any of Aspects 1-18, wherein the multi-voltage domain device is a monolithic device.

Aspect 20: A multi-voltage domain device, comprising: a semiconductor layer comprising a first main surface and a second main surface arranged opposite to the first main surface, wherein the semiconductor layer comprises: a first region comprising first circuitry, a second region comprising second circuitry, and an isolation region that electrically isolates the first region and the second region in a lateral direction in order to electrically isolate the first circuitry and the second circuitry, wherein the lateral direction extends parallel to the first main surface and the second main surface; an insulator layer arranged on the first main surface of the semiconductor layer; a first coil arranged in the insulator layer, wherein the first coil is electrically coupled to the first circuitry and is isolated from the second region, wherein the first coil has a first center axis around which first windings of the first coil are wound, wherein the first windings define a first core area of the first coil that extends along the first center axis, and wherein the first center axis extends parallel to the lateral direction; and a second coil arranged in the insulator layer and laterally separated from the first coil in the lateral direction by an insulator material of the insulator layer, wherein the second coil is electrically coupled to the second circuitry and is isolated from the first region, wherein the second coil has a second center axis around which second windings of the second coil are wound, wherein the second windings define a second core area of the second coil that extends along the second center axis, and wherein the second center axis extends parallel to the lateral direction, wherein the first core area is at least partially aligned with the second core area in the lateral direction, wherein the first coil and the second coil are magnetically coupled to each other in the lateral direction based on an alignment of the first core area with the second core area.

Aspect 21: The multi-voltage domain device of Aspect 20, further comprising: a wafer insulator layer comprising a third main surface; wherein the second main surface of the semiconductor layer is arranged at the third main surface of the wafer insulator layer, and wherein the isolation region includes at least one trench isolation barrier that extends vertically from the first main surface to the third main surface.

Aspect 22: The multi-voltage domain device of Aspect 21, further comprising a silicon-on-insulator (SOI) wafer comprising the semiconductor layer and the wafer insulator layer.

Aspect 23: The multi-voltage domain device of any of Aspects 20-22, wherein the multi-voltage domain device is a monolithic device.

Aspect 24: The multi-voltage domain device of any of Aspects 20-23, wherein the second region comprises third circuitry, and wherein the multi-voltage domain device further comprises a third coil arranged in the insulator layer and laterally separated from the first coil in the lateral direction by the insulator material of the insulator layer, wherein the third coil is electrically coupled to the third circuitry and is isolated from the first region, wherein the third coil has a third center axis around which third windings of the third coil are wound, wherein the third windings define a third core area of the third coil that extends along the third center axis, and wherein the third center axis extends parallel to the lateral direction, wherein the third core area is at least partially aligned with the first core area in the lateral direction, and wherein the first coil and the third coil are magnetically coupled to each other in the lateral direction based on an alignment of the first core area with the third core area.

Aspect 25: The multi-voltage domain device of Aspect 24, wherein the second center axis and the third center axis extend through the first core area.

Aspect 26: The multi-voltage domain device of Aspect 24, wherein the second coil has a first quantity of windings and the third coil has a second quantity of windings that is different from the first quantity of windings.

Aspect 27: A multi-voltage domain device, comprising: a circuit substrate comprising a first main surface and a second main surface arranged opposite to the first main surface, wherein the circuit substrate comprises: a first region comprising first circuitry, a second region comprising second circuitry, a third region comprising third circuitry, and at least one isolation region that electrically isolates the first region and the second region in a first lateral direction in order to electrically isolate the first circuitry and the second circuitry, electrically isolates the first region and the third region in the first lateral direction in order to electrically isolate the first circuitry and the third circuitry, and electrically isolates the second region and the third region in a second lateral direction in order to electrically isolate the second circuitry and the third circuitry; an insulator layer arranged on the first main surface of the circuit substrate; a first coil arranged in the insulator layer, wherein the first coil is electrically coupled to the first circuitry and is isolated from the second region and the third region, wherein the first coil has a first center axis around which first windings of the first coil are wound, wherein the first windings define a first core area of the first coil that extends along the first center axis, and wherein the first center axis extends parallel to the first lateral direction; a second coil arranged in the insulator layer and laterally separated from the first coil in the first lateral direction by an insulator material of the insulator layer, wherein the second coil is electrically coupled to the second circuitry and is isolated from the first region and the third region, wherein the second coil has a second center axis around which second windings of the second coil are wound, wherein the second windings define a second core area of the second coil that extends along the second center axis, and wherein the second center axis extends parallel to the first lateral direction; and a third coil arranged in the insulator layer, laterally separated from the first coil in the first lateral direction by the insulator material of the insulator layer and laterally separated from the second coil in the second lateral direction by the insulator material of the insulator layer, wherein the third coil is electrically coupled to the third circuitry and is isolated from the first region and the second region, wherein the third coil has a third center axis around which third windings of the third coil are wound, wherein the third windings define a third core area of the third coil that extends along the third center axis, and wherein the third center axis extends parallel to the first lateral direction, wherein the second core area is at least partially aligned with the first core area in the first lateral direction, wherein the third core area is at least partially aligned with the first core area in the first lateral direction, wherein the first coil and the second coil are magnetically coupled to each other in the first lateral direction based on an alignment of the first core area with the second core area, and wherein the first coil and the third coil are magnetically coupled to each other in the first lateral direction based on an alignment of the first core area with the third core area.

Aspect 28: A multi-voltage domain device, comprising: a circuit substrate comprising a first main surface and a second main surface arranged opposite to the first main surface, wherein the circuit substrate comprises: a first region comprising first circuitry, a second region comprising second circuitry and third circuitry, and an isolation region that electrically isolates the first region and the second region in a lateral direction in order to electrically isolate the first circuitry from the second circuitry and the first circuitry from the third circuitry, wherein the lateral direction extends parallel to the first main surface and the second main surface; an insulator layer arranged on the first main surface of the circuit substrate; a first coil arranged in the insulator layer, wherein the first coil is electrically coupled to the first circuitry and is isolated from the second region, wherein the first coil has a first center axis around which first windings of the first coil are wound, wherein the first windings define a first core area of the first coil that extends along the first center axis, and wherein the first center axis extends parallel to the lateral direction; a second coil arranged in the insulator layer and laterally separated from the first coil in the lateral direction by an insulator material of the insulator layer, wherein the second coil is electrically coupled to the second circuitry and is isolated from the first region, wherein the second coil has a second center axis around which second windings of the second coil are wound, wherein the second windings define a second core area of the second coil that extends along the second center axis, and wherein the second center axis extends parallel to the lateral direction; and a third coil arranged in the insulator layer and laterally separated from the first coil in the lateral direction by the insulator material of the insulator layer, wherein the third coil is electrically coupled to the third circuitry and is isolated from the first region, wherein the third coil has a third center axis around which third windings of the third coil are wound, wherein the third windings define a third core area of the third coil that extends along the third center axis, and wherein the third center axis extends parallel to the lateral direction, wherein the second core area is at least partially aligned with the first core area in the lateral direction, wherein the third core area is at least partially aligned with the first core area in the lateral direction, wherein the first coil and the second coil are magnetically coupled to each other in the lateral direction based on an alignment of the first core area with the second core area, and wherein the first coil and the third coil are magnetically coupled to each other in the lateral direction based on an alignment of the first core area with the third core area.

Aspect 29: A system configured to perform one or more operations recited in one or more of Aspects 1-28.

Aspect 30: An apparatus comprising means for performing one or more operations recited in one or more of Aspects 1-28.

Aspect 31: A non-transitory computer-readable medium storing a set of instructions, the set of instructions comprising one or more instructions that, when executed by a device, cause the device to perform one or more operations recited in one or more of Aspects 1-28.

Aspect 32: A computer program product comprising instructions or code for executing one or more operations recited in one or more of Aspects 1-28.

The foregoing disclosure provides illustration and description, but is not intended to be exhaustive or to limit the implementations to the precise form disclosed. Modifications and variations are possible in light of the above disclosure or may be acquired from practice of the implementations.

As used herein, the term component is intended to be broadly construed as hardware, firmware, or a combination of hardware and software. It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code-it being understood that software and hardware can be designed to implement the systems and/or methods based on the description herein.

Any of the processing components may be implemented as a central processing unit (CPU) or other processor reading and executing a software program from a non-transitory computer-readable recording medium such as a hard disk or a semiconductor memory device. For example, instructions may be executed by one or more processors, such as one or more CPUs, digital signal processors (DSPs), general-purpose microprocessors, application-specific integrated circuits (ASICs), field programmable logic arrays (FPLAs), programmable logic controller (PLC), or other equivalent integrated or discrete logic circuitry. Accordingly, the term “processor,” as used herein refers to any of the foregoing structures or any other structure suitable for implementation of the techniques described herein. Software may be stored on a non-transitory computer-readable medium such that the non-transitory computer readable medium includes a program code or a program algorithm stored thereon which, when executed, causes the processor, via a computer program, to perform the steps of a method.

A controller including hardware may also perform one or more of the techniques of this disclosure. A controller, including one or more processors, may use electrical signals and digital algorithms to perform its receptive, analytic, and control functions, which may further include corrective functions. Such hardware, software, and firmware may be implemented within the same device or within separate devices to support the various techniques described in this disclosure.

A signal processing circuit and/or a signal conditioning circuit may receive one or more signals (e.g., measurement signals) from one or more components in the form of raw measurement data and may derive, from the measurement signal further information. Signal conditioning, as used herein, refers to manipulating an analog signal in such a way that the signal meets the requirements of a next stage for further processing. Signal conditioning may include converting from analog to digital (e.g., via an analog-to-digital converter), amplification, filtering, converting, biasing, range matching, isolation and any other processes required to make a signal suitable for processing after conditioning.

Some implementations may be described herein in connection with thresholds. As used herein, satisfying a threshold may refer to a value being greater than the threshold, more than the threshold, higher than the threshold, greater than or equal to the threshold, less than the threshold, fewer than the threshold, lower than the threshold, less than or equal to the threshold, equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

Further, it is to be understood that the disclosure of multiple acts or functions disclosed in the specification or in the claims may not be construed as to be within the specific order. Therefore, the disclosure of multiple acts or functions will not limit these to a particular order unless such acts or functions are not interchangeable for technical reasons. Furthermore, in some implementations, a single act may include or may be broken into multiple sub acts. Such sub acts may be included and part of the disclosure of this single act unless explicitly excluded.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A multi-voltage domain device, comprising:
a circuit substrate comprising a first main surface and a second main surface arranged opposite to the first main surface, wherein the circuit substrate comprises:
a first region comprising first circuitry that operates in a first voltage domain,
a second region comprising second circuitry that operates in a second voltage domain, and
an isolation region that electrically isolates the first region and the second region in a lateral direction that extends parallel to the first main surface and the second main surface;
an insulator layer arranged on the first main surface of the circuit substrate;
a first coil arranged in the insulator layer, wherein the first coil is electrically coupled to the first circuitry and is isolated from the second region, wherein the first coil has a first center axis around which first windings of the first coil are wound, and wherein the first center axis extends parallel to the lateral direction; and
a second coil arranged in the insulator layer and laterally separated from the first coil in the lateral direction by an insulator material of the insulator layer, wherein the second coil is electrically coupled to the second circuitry and is isolated from the first region, wherein the second coil has a second center axis around which second windings of the second coil are wound, and wherein the second center axis extends parallel to the lateral direction and is aligned with the first center axis,
wherein the first coil and the second coil are magnetically coupled to each other in the lateral direction based on an alignment of the first center axis with the second center axis.

2. The multi-voltage domain device of claim 1, wherein the first center axis is collinear with a first magnetic axis of the first coil and the second center axis is collinear with a second magnetic axis of the second coil.

3. The multi-voltage domain device of claim 1, wherein the insulator layer is a stack-insulator layer comprising a plurality of sub-insulator layers,
wherein the first coil comprises a first plurality of conductive layers and a first plurality of conductive vias integrated in the insulator layer, and
wherein the second coil comprises a second plurality of conductive layers and a second plurality of conductive vias integrated in the insulator layer.

4. The multi-voltage domain device of claim 3, wherein the first plurality of conductive vias extend vertically between first plurality of conductive layers, and
the second plurality of conductive vias extend vertically between second plurality of conductive layers.

5. The multi-voltage domain device of claim 1, wherein the first coil and the second coil are encapsulated by the insulator material of the insulator layer.

6. The multi-voltage domain device of claim 1, wherein the first coil has a first coil width, and
wherein the second coil has a second coil width that is different from the first coil width.

7. The multi-voltage domain device of claim 6, wherein the first coil width is uniform or substantially uniform throughout the first coil, and
wherein the second coil width is uniform or substantially uniform throughout the second coil.

8. The multi-voltage domain device of claim 1, wherein at least one of the first coil or the second coil is a tapered coil having a respective tapered coil width that changes in the lateral direction.

9. The multi-voltage domain device of claim 1, wherein the first coil has first U-shape comprising a first coil end and a second coil end,
wherein the second coil has second U-shape comprising a third coil end and a fourth coil end,
wherein the first coil end of the first coil is aligned with the third coil end of the second coil across the isolation region, and
wherein the second coil end of the first coil is aligned with the fourth coil end of the second coil across the isolation region.

10. The multi-voltage domain device of claim 9, wherein the first coil has a first coil opening at the first coil end and a second coil opening at the second coil end,
wherein the second coil has a third coil opening at the third coil end and a fourth coil opening at the fourth coil end,
wherein the first coil opening faces the third coil opening,
wherein the third coil opening faces the first coil opening,
wherein the second coil opening faces the fourth coil opening, and
wherein the fourth coil opening faces the second coil opening.

11. The multi-voltage domain device of claim 9, wherein a first geometry of the first coil is a mirrored representation of a second geometry of the second coil across the isolation region.

12. The multi-voltage domain device of claim 1, wherein the isolation region comprises one or more trench isolation barriers, and
wherein each of the one or more trench isolation barriers extends vertically from the first main surface to the second main surface.

13. The multi-voltage domain device of claim 1, wherein the first coil comprises at least two first terminals that are arranged vertically over the first region and are electrically coupled to the first circuitry, and
wherein the second coil comprises at least two second terminals that are arranged vertically over the second region and are electrically coupled to the second circuitry.

14. The multi-voltage domain device of claim 1, wherein the first coil and the second coil are configured to utilize a magnetic coupling to transmit communication signals or power signals between the first circuitry and the second circuitry, over the isolation region.

15. The multi-voltage domain device of claim 1, wherein the circuit substrate is a semiconductor substrate.

16. A multi-voltage domain device, comprising:
a semiconductor layer comprising a first main surface and a second main surface arranged opposite to the first main surface, wherein the semiconductor layer comprises:
a first region comprising first circuitry,
a second region comprising second circuitry, and
an isolation region that electrically isolates the first region and the second region in a lateral direction in order to electrically isolate the first circuitry and the second circuitry, wherein the lateral direction extends parallel to the first main surface and the second main surface;
an insulator layer arranged on the first main surface of the semiconductor layer;
a first coil arranged in the insulator layer, wherein the first coil is electrically coupled to the first circuitry and is isolated from the second region, wherein the first coil has a first center axis around which first windings of the first coil are wound, wherein the first windings define a first core area of the first coil that extends along the first center axis, and wherein the first center axis extends parallel to the lateral direction; and
a second coil arranged in the insulator layer and laterally separated from the first coil in the lateral direction by an insulator material of the insulator layer, wherein the second coil is electrically coupled to the second circuitry and is isolated from the first region, wherein the second coil has a second center axis around which second windings of the second coil are wound, wherein the second windings define a second core area of the second coil that extends along the second center axis, and wherein the second center axis extends parallel to the lateral direction,
wherein the first core area is at least partially aligned with the second core area in the lateral direction,
wherein the first coil and the second coil are magnetically coupled to each other in the lateral direction based on an alignment of the first core area with the second core area.

17. The multi-voltage domain device of claim 16, further comprising:
a wafer insulator layer comprising a third main surface;
wherein the second main surface of the semiconductor layer is arranged at the third main surface of the wafer insulator layer, and
wherein the isolation region includes at least one trench isolation barrier that extends vertically from the first main surface to the third main surface.

18. The multi-voltage domain device of claim 17, further comprising a
silicon-on-insulator (SOI) wafer comprising the semiconductor layer and the wafer insulator layer.

19. The multi-voltage domain device of claim 16, wherein the multi-voltage domain device is a monolithic device.

20. The multi-voltage domain device of claim 16, wherein the second region comprises third circuitry, and
wherein the multi-voltage domain device further comprises a third coil arranged in the insulator layer and laterally separated from the first coil in the lateral direction by the insulator material of the insulator layer, wherein the third coil is electrically coupled to the third circuitry and is isolated from the first region, wherein the third coil has a third center axis around which third windings of the third coil are wound, wherein the third windings define a third core area of the third coil that extends along the third center axis, and wherein the third center axis extends parallel to the lateral direction,
wherein the third core area is at least partially aligned with the first core area in the lateral direction, and
wherein the first coil and the third coil are magnetically coupled to each other in the lateral direction based on an alignment of the first core area with the third core area.

21. The multi-voltage domain device of claim 20, wherein the second center axis and the third center axis extend through the first core area.

22. A multi-voltage domain device, comprising:
a circuit substrate comprising a first main surface and a second main surface arranged opposite to the first main surface, wherein the circuit substrate comprises:
a first region comprising first circuitry,
a second region comprising second circuitry,
a third region comprising third circuitry, and
at least one isolation region that electrically isolates the first region and the second region in a first lateral direction in order to electrically isolate the first circuitry and the second circuitry, electrically isolates the first region and the third region in the first lateral direction in order to electrically isolate the first circuitry and the third circuitry, and electrically isolates the second region and the third region in a second lateral direction in order to electrically isolate the second circuitry and the third circuitry;
an insulator layer arranged on the first main surface of the circuit substrate;
a first coil arranged in the insulator layer, wherein the first coil is electrically coupled to the first circuitry and is isolated from the second region and the third region, wherein the first coil has a first center axis around which first windings of the first coil are wound, wherein the first windings define a first core area of the first coil that extends along the first center axis, and wherein the first center axis extends parallel to the first lateral direction;
a second coil arranged in the insulator layer and laterally separated from the first coil in the first lateral direction by an insulator material of the insulator layer, wherein the second coil is electrically coupled to the second circuitry and is isolated from the first region and the third region, wherein the second coil has a second center axis around which second windings of the second coil are wound, wherein the second windings define a second core area of the second coil that extends along the second center axis, and wherein the second center axis extends parallel to the first lateral direction; and
a third coil arranged in the insulator layer, laterally separated from the first coil in the first lateral direction by the insulator material of the insulator layer and laterally separated from the second coil in the second lateral direction by the insulator material of the insulator layer, wherein the third coil is electrically coupled to the third circuitry and is isolated from the first region and the second region, wherein the third coil has a third center axis around which third windings of the third coil are wound, wherein the third windings define a third core area of the third coil that extends along the third center axis, and wherein the third center axis extends parallel to the first lateral direction,
wherein the second core area is at least partially aligned with the first core area in the first lateral direction,
wherein the third core area is at least partially aligned with the first core area in the first lateral direction,
wherein the first coil and the second coil are magnetically coupled to each other in the first lateral direction based on an alignment of the first core area with the second core area, and
wherein the first coil and the third coil are magnetically coupled to each other in the first lateral direction based on an alignment of the first core area with the third core area.
